(19) United States
(12) Patent Application Publication
(10) Pub. No.: US 2009/0199141 A1
(43) Pub. Date: Aug. 6, 2009

(54) SYSTEMS AND METHODS FOR PROTOTYPING AND TESTING ELECTRICAL CIRCUITS IN NEAR REAL-TIME

(75) Inventor: Karam Michael Noujeim, Sunnyvale, CA (US)

Correspondence Address: FLIESLER MEYER LLP, 650 CALIFORNIA STREET, 14TH FLOOR, SAN FRANCISCO, CA, 94108, US

(73) Assignee: ANRITSU COMPANY, Morgan Hill, CA (US)

(21) Appl. No.: 12/026,732

(22) Filed: Feb. 6, 2008

(51) Int. Cl. G01R 31/28; G06F 17/50

(52) U.S. Cl. 716/5; 29/593

(57) ABSTRACT

A system for fabricating, testing, and modifying a prototype of an electrical circuit comprises a materials printer including a holder for positioning a substrate. The materials printer is adapted to receive information describing the prototype and is further adapted to fabricate the prototype on the substrate based on the information. An electrical measuring instrument associated with the holder is adapted to be placed in electrical communication with the prototype when the prototype is received by the holder. A display device receives a plurality of measurements of the prototype from the electrical measuring instrument.

### BACKGROUND OF THE INVENTION

Electrical circuit design covers a wide array of applications ranging from complex electronic systems to individual components within an integrated circuit. Reducing an electrical circuit design from theory to practice involves commonly a series of steps. These include for example the synthesis of complex circuits based on first principles and computer-aided design, followed by the fabrication of physical prototypes. The physical prototypes are then tested against specifications, and modifications to them are made in an attempt to achieve compliance. Since compliance with specifications is often difficult to achieve after a first prototype, the modify-fabricate-test cycle is repeated until full compliance is achieved.

Circuits and components of circuits operated at high frequencies, e.g. microwave frequencies, exhibit responses that can vary substantially with component geometry and dimensions, material properties, and other factors. For example, a relatively simple component such as a low pass filter can exhibit a frequency response that is highly dependent on the dimensions and material composition of the substrate and conductor traces comprising the low pass filter. Tailoring the dimensions of such traces in order to achieve a target frequency response is an objective of a designer's layout. For example, if the stub traces of a microwave low-pass filter are made shorter, the frequency response shifts high in frequency. In contrast, if they are made longer, the frequency response shifts low in frequency. A designer may estimate target dimensions to achieve the target frequency response and procure a series of prototypes selected based on the target dimensions. However, the frequency response of microwave circuits and components can vary substantially from predicted results, causing target dimensions to be unsuitable as a basis for design and can result in the designer having to procure prototypes selected based on new target dimensions estimated based on the response of the initial batch of prototypes. The design process can require multiple iterations of fabrication, making the design process both laborious and expensive.

### BRIEF DESCRIPTION OF THE DRAWINGS

Further details of embodiments of the present invention are explained with the help of the attached drawings in which:

FIG. 1 is a schematic representation of an embodiment of a system to fabricate and test a prototype of an electrical circuit in accordance with the present invention.

FIG. 2 is a flow chart of an embodiment of a method of fabricating, testing, and modifying a prototype of an electrical circuit, in accordance with the present invention.

FIG. 3 is a flow chart of an embodiment of a method to determine a final layout by fabricating, testing, and modifying one or more prototypes of an electrical circuit in accordance with the present invention.

FIG. 4 is a flow chart of an alternative embodiment of a method to determine a final layout by fabricating, testing, and modifying one or more groups of prototypes of an electrical circuit in accordance with the present invention.

### DETAILED DESCRIPTION OF THE DRAWINGS

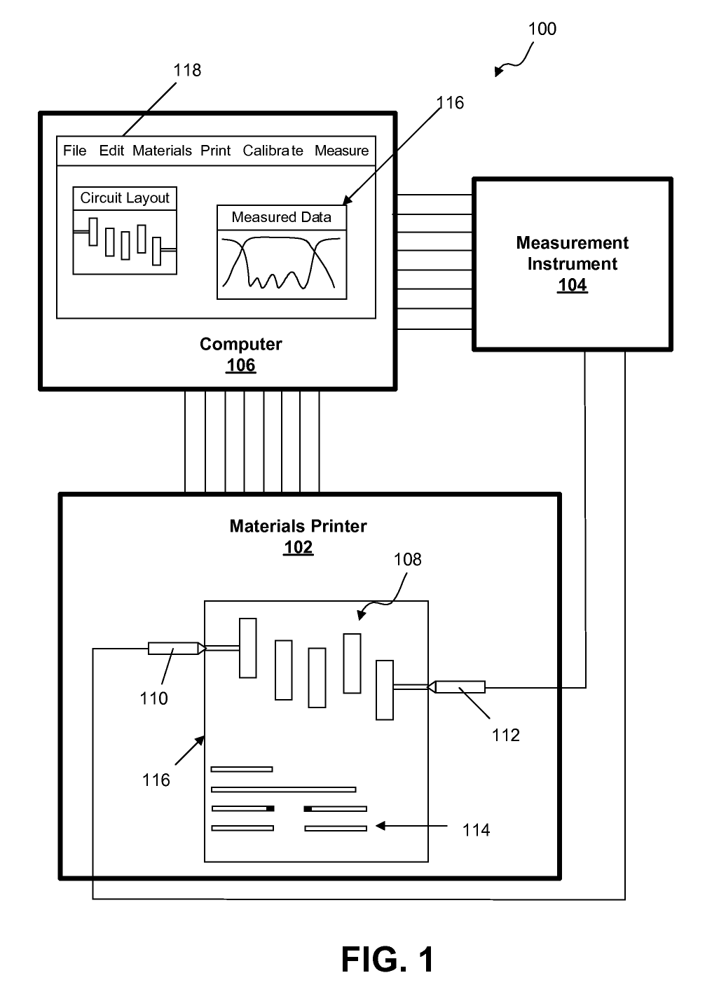

Embodiments of systems and methods in accordance with the present invention can be applied to reduce design time for an electrical circuit. FIG. 1 is a schematic representation of an embodiment of a system 100 in accordance with the present invention comprising a materials printer 102 associated with a measurement instrument 104. Advances in material-printing technologies have enabled fabrication of multilayer circuits, and have been applied in production of such devices as radio-frequency identification (“RFID”) tags to reduce costs associated with production itself. Nano-powders of various metals, dielectrics, and other materials are available in mixtures that can be dispensed by inkjets, aerosol jets, laser processing and other printing techniques onto wafers, substrates, tapes, and other planar or non-planar surfaces.

The materials printer of the embodiment can receive information describing one or more components and/or circuits and can print the one or more components and/or circuits to a surface. The information received can include executable instructions, such as a sequence of fabrication steps (e.g., a recipe), or alternatively, the information can include desired resultant structure, such as a circuit layout. If the information includes desired result structure, the materials printer can include software and circuitry to determine achievable component layout and fabrication techniques.

In the embodiment of FIG. 1, the materials printer 102 is communicatively connected with a computer 106 to receive information from the computer 106 and optionally to communicate information to the computer 106 (such as printer status identifiers, test measurement results, etc.). The computer 106 can be locally connected with the materials printer 102, for example by way of a standard interface such as a general purpose interface bus (“GPIB”), a Universal Serial Bus (“USB”), or by a proprietary interface. Alternatively, the computer 106 can communicate with the materials printer 102 through a network connection such as a routing device connected with the materials printer 102 by wire and/or wirelessly. In still other embodiments, the computer can be remotely connected to the materials printer, such as through an internet connection. The computer 106 can optionally provide a local or remote workstation including software and hardware for the user to produce a layout of the electrical circuit and/or simulate an electrical circuit. (As used hereinafter, electrical circuit can refer to a simple electrical circuit, a complex electrical circuit, or a subcomponent of the simple and/or complex electrical circuit). A remote workstation, for example, can be provided to a user by a remote server that hosts electrical circuit layout and design software applications and allow the server to push or be queried for information.

Information can be prepared and sent to the materials printer 102 to fabricate a prototype 108 from a layout of an electrical circuit when the layout for the electrical circuit is in a condition to have its performance tested. If the information is a sequence of fabrication steps, for example, the computer 106 can generate the sequence of fabrication steps based on the electrical circuit layout with additional input from a user, where desired. Additional input can include material selection for certain portions of the circuit, frequency range of characterization, probe contact locations, etc. The computer 106 generates information to control the physical characteristics and dimensional properties of the materials to be printed. Such control can enable compatibility with “standard-cell” libraries commonly provided by semiconductor, thin-film, and printed-circuit fabrication vendors. However, fabrication need not be restricted to standard-cell libraries, and additional user inputs defining dimensions (e.g., width and thickness) can be supplied. Once the computer 106 generates the information (or while the computer 106 generates the information), the information is communicated to the materials printer 108. As mentioned above, in an alternative embodiment, the materials printer 108 can receive the layout of the electrical circuit and optionally a user's inputs to generate a sequence of fabrication steps using software and circuitry associated with the materials printer 108. In still further embodiments, the computer 106 can be a component of the materials printer 102 or alternatively a component of the measurement instrument 104.

The materials printer 102 can fabricate a prototype 108 based on the information. Printing can take place in a typical work environment, and need not necessarily require a clean room environment. The materials printer 102 can be as small as a typical desktop printer, although the system need not be restricted by the size of the materials printer, or any other component. Printing technologies can apply one or more techniques ranging, for example, from dispensing fluidic materials from a nozzle (e.g., inkjet printing, aerosol printing) to laser-guided gel created as part of an evaporated process. For example, Maskless Mesoscale Material Deposition (M³D®) from Optomec® is an additive process that guides evaporated particles by laser, and can produce pattern features as small as 10 microns, and as large as 100 microns. The scale of the prototype 108 need not necessarily be 1:1 for good signal response, allowing an electrical circuit layout to be scaled up to avoid limitations of the printing technology applied. However, certain size-dependent affects can occur at high frequencies that may not occur at lower frequencies, thus such potential affects are accounted for or considered.

A prototype 108 can be built having multiple layers using inkjet technology to form traces, vias, contacts, air bridges, resistors, inductors, capacitors and other semiconductor features, using materials which are conducting, semi-conducting, insulating, passive, active, organic, or non-organic materials. The capabilities and material characteristics achievable with inkjet technology enable creation of three-dimensional electrical circuits. For example, Seiko Epson of Japan has demonstrated a 20-layer circuit board fabricated by inkjet technology using an inkjet system to alternately “draw” patterns and form layers on the board using two types of ink: a conductive ink containing a dispersion of silver micro-particles measuring from several nanometers to several tens of nanometers in diameter, and an insulator ink. Once the printing process finishes, the prototype can be cured, for example by laser or heating and measurements can then take place.

In other embodiments of systems and methods, information can be prepared and sent to a materials printer 102 from a computer 106 to fabricate a group of prototypes from a baseline layout of an electrical circuit. The group of prototypes can comprise, for example, one or more physical characteristics that are centered on, and varied from that of the baseline layout to assist in selecting a physical characteristic that produces a target response, or alternatively that produces a new baseline layout from which an additional group of prototypes can be fabricated. As above, the information can include simple commands or complex objectives, such as a sequence of fabrication steps or a baseline circuit layout. Once the computer 106 generates the information (or while the computer 106 generates the information), the information is communicated to the materials printer 108. Further, as above, the computer 106 can be a component of the materials printer 102 or alternatively a component of the measurement instrument 104.

In addition to the prototype 108 or group of prototypes (referred to hereinafter collectively as “test subject”), the materials printer 102 can fabricate a calibration standard(s) 114 that can be selected by the computer 106, the user, and/or the materials printer 102 based on the baseline electrical circuit layout and the operating conditions for which the test subject is to be characterized. For example, if the test subject is intended to be measured by a vector network analyzer (VNA), performance can be evaluated based on response in the frequency domain. The response describes the behavior of the test subject with frequency over a certain frequency range chosen early on in the design process. An appropriate calibration standard is printed for calibrating the measurement instrument 104 for measuring performance. The computer 106 can communicate the specified frequency range of operation to the measurement instrument 104, and calibration of the measurement instrument 104 is performed based on the printed calibration standards 114. Subsequent measurements of the test subject are performed based on the calibration of the measurement instrument 104 with the calibration standard 114. Use of a calibration standard allows the measurement instrument to correct for errors, so that measurements can be taken of electrical circuit performance in reference planes that the user requires.

Once the printing process and curing are complete, probes 110,112 can be landed at appropriate locations of a prototype 108 in an automated (or semi-automated) or manual fashion using a probe positioner. Probe systems commonly rely on probe positioners that identify where a fiducial is, and from the fiducial or the reference point on the electrical circuit can access the electrical circuit. Probes 110,112 can be connected with a prototype 108 through assistance of a v-connector, or some other type of connector. In other embodiments, the probes 110,112 can be contact-less probes placed in communicative proximity with the prototype 108. In still other embodiments, probes 110,112 can be mounted to a surface, and printing can take place on the surface extending from or to the probes 110,112. Where the test subject is a group of prototypes, a plurality of probes can be mounted to a surface, and printing can take place on the surface extending from or to the probes for each of the prototypes.

In another embodiment, a substrate 116 on which the test subject is formed is made accessible to one or more electrical measurement instruments 104. For example, in one embodiment, the substrate 116 can be repositioned from a stage to a holder adapted to receive the substrate 116 from the materials printer 102. In other embodiments, the substrate can also be the stage on which fabrication takes place, and on which measurements are performed by a measurement instrument 104. For example, the holder can comprise a vacuum chuck that holds a substrate 116 and acts as a stage while printing is taking place and while measurements are taking place. The holder can be moved relative to fabrication equipment and measurement instrument(s) or fabrication equipment and measurement instrument(s) can be moved relative to the holder. For example, inkjet nozzles can be moved relative to the holder and subsequently removed to allow positioning of probes at contact points of the prototype or a prototype from a group of prototypes.

Embodiments of systems and methods in accordance with the present invention can be applied with a selective degree of automation. For example, a design experiment can include a group of prototypes printed with variations in layout branching from a baseline layout of an electrical circuit. The system can be instructed to complete measurements for some or all of the prototypes from the group of prototypes, and to produce results from measurement data. Results can be produced as desired by a user. For example, results can comprise raw measurement data or conditioned measurement data (for example, normalized against target results). Optionally, the system can apply logic to the measurement data to predict a new baseline, or a new group of prototypes re-centered based on the measured data, for example. A display device 116 can receive the results and display the results. The display device 116 can be a display screen of the computer 106, a display screen of the measurement instrument 104, or a display screen of the materials printer 102, for example. Alternatively, the results can be included in a print-out from the measurement instrument 104 or computer 106.

In still other embodiments of systems and methods in accordance with the present invention, logic circuitry can be provided to perform two or more iterations of prototyping by performing multiple pre-defined fabrication and measurement. Alternatively, logic circuitry can be provided to perform recursive prototyping. Thus, target results can be defined by a user (or by a database) and a prototype or group of prototypes can be fabricated and measured, and the results are compared with the target results.

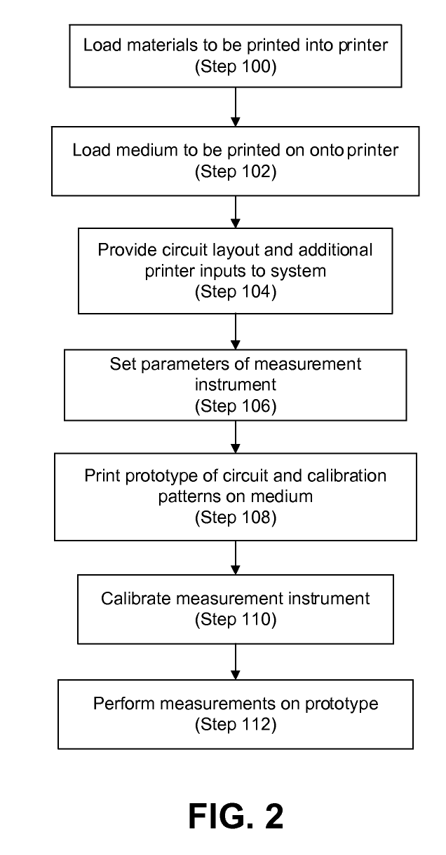

Referring to FIG. 2, a flow chart of an embodiment of a method to fabricate and test a prototype of an electrical circuit in accordance with the present invention is shown. A materials printer can be loaded with materials (e.g., silver, gold) required to fabricate the prototype (Step 100). As mentioned above, the materials can be one or more of conducting, semi-conducting, insulating, passive, active, organic, or non-organic materials. A substrate (also referred to herein as a medium) is provided to the materials printer. The substrate need not be planar, but rather can have curvature, and may be rigid, semi-rigid or flexible, depending on the materials used to form the circuit, and the dimensions and properties of the circuit itself (Step 102). For example, the substrate can comprise a commonly used semiconductor substrate such as gallium arsenide or silicon, or the substrate can be a material such as used for PCB (i.e., phenolic or glass-epoxy board with copper clad on one or both sides). An electrical circuit layout is provided to a system connected with the materials printer (e.g., one or more of a computer, the materials printer, and a measurement instrument), and additional input from a user is provided to the system (Step 104). The electrical circuit layout and additional input generates information that controls fabrication of a prototype on the substrate by the materials of the material printer. Where the circuit is dependent on operating parameters (i.e., frequency, voltage), such operating parameters are provided to the system by a user (Step 106). The materials printer can then print the electrical circuit on the substrate to form a prototype based on the information, and can further print calibration patterns based on one or both of the information and the operating parameters (Step 108). The measurement instrument is calibrated automatically, semi-automatically, or manually, by placing probes (contact, or non-contact) in communication with the printed calibration standard (Step 110). The probes (or alternatively, dedicated probes) are placed in electrical communication with the prototype to apply signals to the circuit, and measure performance characteristics (Step 112).

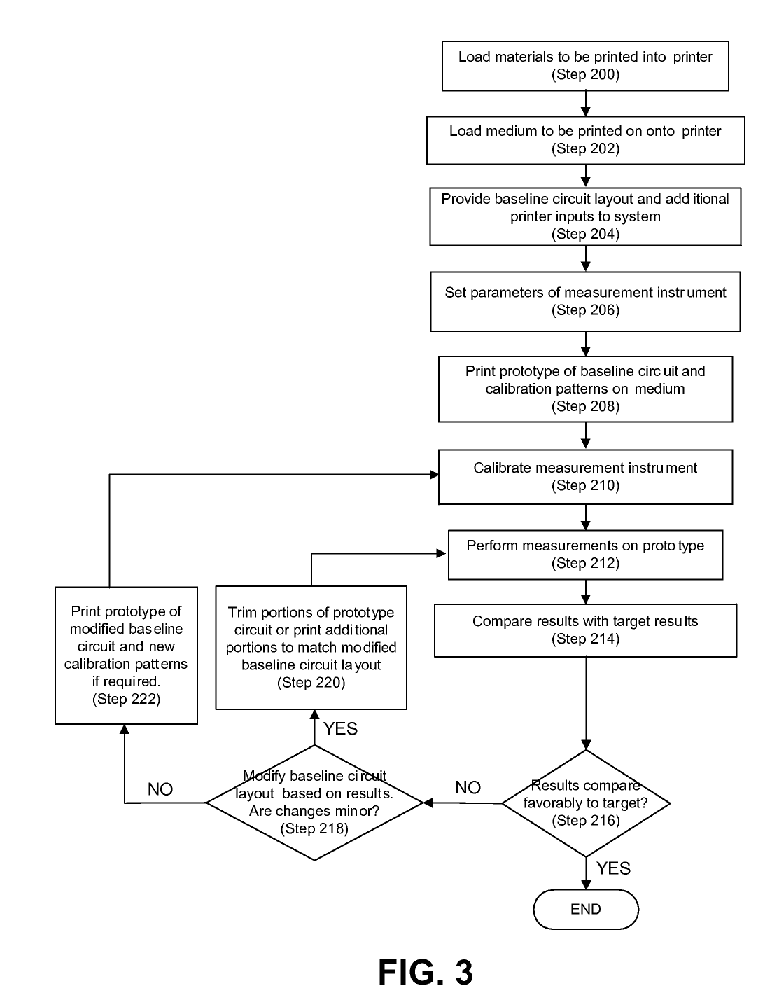

Referring to FIG. 3, a flow chart of an embodiment of a method to determine a final layout by fabricating, testing, and modifying one or more prototypes of an electrical circuit in accordance with the present invention. A materials printer can be loaded with materials required to fabricate the prototype (Step 200). A substrate is provided to the materials printer (Step 202). A baseline electrical circuit layout is provided to a system associated with the materials printer, and additional input from a user is provided to the system (Step 204). The baseline electrical circuit layout and additional input generates information that controls fabrication of a prototype on the substrate by the materials of the material printer. Where the baseline electrical circuit is dependent on operating parameters (i.e., frequency, voltage), such operating parameters are provided to the system by a user (Step 206). The materials printer can then print the electrical circuit to the substrate to form a prototype based on the information, and can further print calibration patterns based on one or both of the information and the operating parameters (Step 208). The measurement instrument is calibrated automatically, semi-automatically, or manually, by placing probes (contact, or non-contact) in communication with the printed calibration standard (Step 210). The probes (or alternatively, dedicated probes) are placed in electrical communication with the prototype to apply signals to the circuit, and measure performance characteristics (Step 212). The results of the performance characteristics measurements can be compared with target results. If the results compare satisfactorily with the target results, the baseline electrical circuit is a satisfactory design, and the method can be completed (Step 214). Optionally, the results and/or baseline electrical circuit is printed or otherwise communicated to a user. If the results do not compared satisfactorily with the target results, the system determines a modification of the baseline electrical circuit using the results (Step 218). The modified baseline electrical circuit is communicated back to the system and modifications to the prototype are carried out (trimming of printed traces by laser for example or the extension of printed traces by additional printing and curing) (Step 220) or a second prototype is formed (Step 222) (optionally the measurement instrument may be recalibrated using the new calibration patterns). The method repeats until the results satisfactorily compare with the target results.

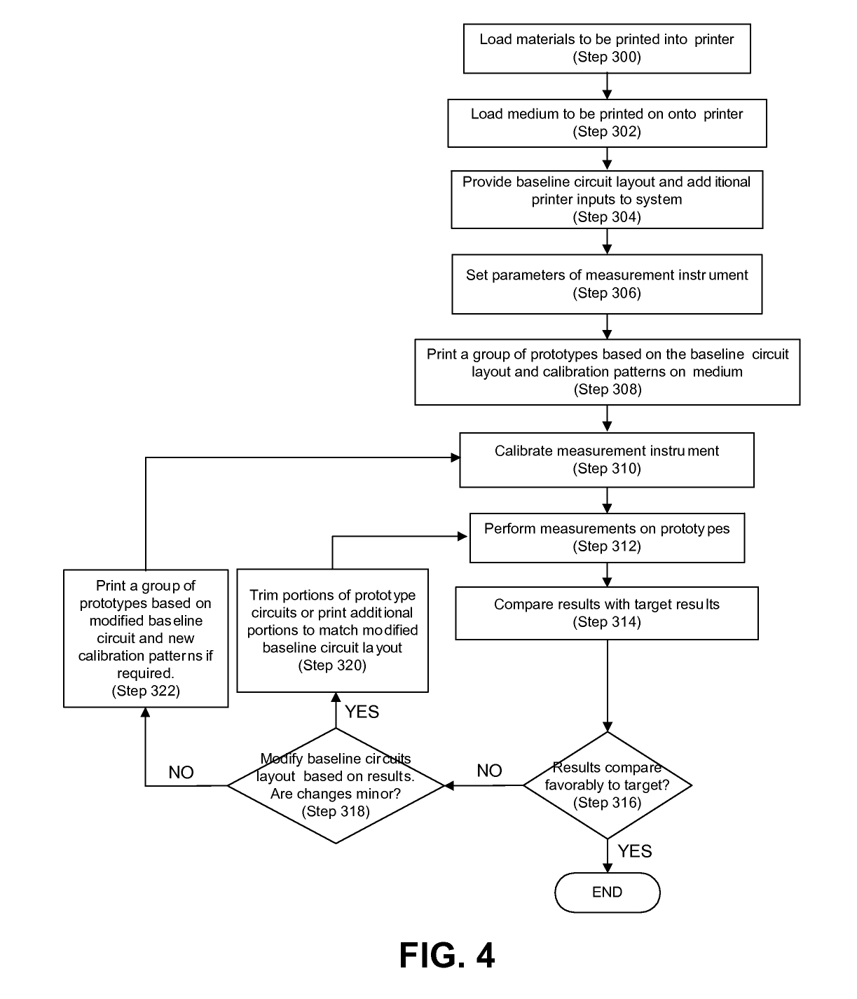

Referring to FIG. 4, a flow chart of an alternative embodiment of a method to determine a final layout by fabricating and testing one or more groups of prototypes of an electrical circuit in accordance with the present invention. A materials printer can be loaded with materials required to fabricate the prototype (Step 300). A substrate is provided to the materials printer (Step 302). A baseline electrical circuit layout is provided to a system associated with the material printer, and additional input from a user is provided to the system (Step 304). The baseline electrical circuit layout and additional input generates information that controls fabrication of a group of prototypes comprising respective electrical circuits having variations of one or more design parameters defined around the baseline electrical circuit layout. The group of prototypes is fabricated on the substrate by the materials of the material printer. Where the baseline electrical circuit is dependent on operating parameters (i.e., frequency, voltage), such operating parameters are provided to the system by a user (Step 306). The materials printer can then print the electrical circuits on the substrate to form the groups of prototypes based on the information, and can further print calibration patterns based on one or both of the information and the operating parameters (Step 308). The measurement instrument is calibrated automatically, semi-automatically, or manually, by placing probes (contact, or non-contact) in communication with the printed calibration standard (Step 310). The probes (or alternatively, dedicated probes) are placed in electrical communication with one or more of the prototypes from the group of prototypes to apply signals to the electrical circuits, and measure performance characteristics (Step 312). The results of the performance characteristics measurements can be compared with target results (Step 314). If the results compare (Step 316) satisfactorily the target results, one (or more) of the prototypes from the group of prototypes includes a satisfactory electrical circuit design, and the method can be completed. Optionally, the results and/or electrical circuit(s) is printed or otherwise communicated to a user. If the results do not compared satisfactorily with the target results, the system determines a modification of the baseline electrical circuit using the results (Step 318). The modified baseline electrical circuit is communicated back to the system and modifications to the prototypes are carried out (trimming of printed traces by laser for example or the extension of printed traces by additional printing and curing) (Step 320) or a second group of prototypes is formed (Step 322) (optionally the measurement instrument may be recalibrated using the new calibration patterns). The method repeats until the results satisfactorily compare with the target results.

A system disclosed herein enables near real-time prototyping and electrical-circuit testing. Prototyping complex circuits and components of such circuits early in the design stage and getting measurement data from circuits and components can reduce a design cycle and associated costs. The lengthy and sequential nature associated with the prototyping and testing of electrical circuits adds considerably to the costs of design and often results in missed deadlines and lost market opportunities. The ability to prototype and measure circuits or portions of circuits near-contemporaneously without the need for masks and chemicals can reduce development cost and shorten the design cycle. Such as system is suited to (though not necessarily limited to) the technological fields of monolithic microwave integrated circuit (MMIC) design (e.g., radio-frequency complementary metal oxide semiconductors (RF CMOS), BiCMOS, gallium arsenide (GaAs), indium phosphide (InP), etc.), packaging, thin-film and printed circuits, for example where fabrication is lengthy and expensive. Other technical fields that could benefit from such an apparatus are board and package-level signal integrity, compliance testing for electromechanical conformance (EMC), and educational applications among others.

The foregoing description of the present invention has been presented for purposes of illustration and description. It is not intended to be exhaustive or to limit the invention to the precise forms disclosed. Many modifications and variations will be apparent to practitioners skilled in this art. The embodiments were chosen and described in order to best explain the principles of the invention and its practical application, thereby enabling others skilled in the art to understand the invention for various embodiments and with various modifications as are suited to the particular use contemplated. It is intended that the scope of the invention be defined by the following claims and their equivalents.

1. A system for fabricating, testing, and modifying a prototype of an electrical circuit comprising:
a materials printer including a holder for positioning a substrate, the materials printer adapted to receive information describing the prototype, the materials printer further adapted to fabricate the prototype on the substrate based on the information;
an electrical measuring instrument associated with the holder;
wherein the electrical measuring instrument is adapted to be placed in electrical communication with the prototype when the prototype is received by the holder; and
a display device to receive a plurality of measurements of the prototype from the electrical measuring instrument.

2. The system of claim 1, further including:
circuitry to determine whether the plurality of measurements satisfies a target result; and
circuitry to determine information describing a second prototype if the plurality of measurements does not satisfy the target result.

3. The system of claim 1, further comprising:
circuitry to determine a plurality of prototypes based on the information describing the prototype;
wherein the materials printer is further adapted to fabricate the plurality of prototypes on the substrate; and
wherein the electrical measuring instrument is adapted to be placed in electrical communication with the plurality of prototype when the plurality of prototypes is received by the holder; and
circuitry to determine information describing a second prototype if the plurality of measurements does not satisfy the target result.

4. The system of claim 1, further comprising:
a computer to communicate the information to the materials printer; and
wherein the computer is one or both of remote from the materials printer and local to the materials printer.

5. The system of claim 1, wherein:
the electrical measuring instrument includes two or more probes for accessing the prototype; and
the two or more probes are movable to allow selective access to the prototype.

6. The system of claim 5, further comprising:
a computer to communicate the information to the materials printer;
wherein the computer is further adapted to provide a command to position the two or more probes based on the information.

7. The system of claim 1, wherein:
the information includes material characteristics and prototype dimensions; and
the information is compatible with standard cell libraries.

8. The system of claim 4, wherein the computer communicates with the materials printer by way of one or both of a wired and wireless network.

9. The system of claim 1, wherein the materials printer is adapted to fabricate the prototype on a non-planar substrate.

10. The system of claim 7, wherein the materials printer is adapted to print materials including one or more of conducting, semi-conducting, insulating, passive, active, organic, non-organic materials.

11. The system of claim 10, wherein the materials printer is adapted to fabricate a prototype including multiple layers and one or more of traces, vias, contacts, and air bridges.

12. The system of claim 10, wherein the prototype includes one or both of a receiving antenna and a transmitting antenna.

13. The system of claim 1, wherein the materials printer is adapted to fabricate a calibration circuit.

14. The system of claim 5, wherein the two or more probes are one or both of a contact probe and a contact-less probe.

15. The system of claim 4, wherein the display device is one or both of a video screen connected with the computer and a print-out.

16. The system of claim 1, wherein:
the materials printer is adapted to print a calibration standard with the prototype; and
the calibration standard is accessible to the electrical measuring instrument.

17. A method of forming and testing a prototype of an electrical circuit comprising:
receiving information describing the prototype at a materials printer;
printing the prototype to a medium using the materials printer based on the information;
positioning the printed prototype to a holder;
accessing the prototype with an electrical measurement instrument;
measuring one or more data of the prototype with the electrical measurement instrument;
communicating the one or more data to a display, wherein the display is one or both of a print-out and a video screen.

18. The method of claim 17, further comprising:
printing a calibration standard to the medium using the materials printer; and
calibrating the electrical measurement instrument using the calibration standard.

19. The method of claim 19, wherein printing the prototype to a medium further includes:
depositing one or more of conducting, semi-conducting, insulating, passive, active, organic, non-organic materials; and
defining one or more of traces, vias, contacts, and air bridges.

20. The method of claim 17, wherein accessing the prototype with an electrical measurement instrument further includes:
accessing conductive portions of the prototype with two or more probes.

21. The method of claim 17, further comprising:
positioning the two or more probes relative to the prototype based on the information.

22. The method of claim 17, further comprising:
determining whether the measurements satisfies a target result; and
determining information describing a second prototype if the measurements do not satisfy the target result.
